(19) United States
(12) Patent Application Publication
(10) Pub. No.: US 2023/0422443 A1
(43) Pub. Date: Dec. 28, 2023

(54) VAPOR CHAMBER STRUCTURE

(71) Applicant: ASIA VITAL COMPONENTS CO., LTD., New Taipei City (TW)

(72) Inventor: Sheng-Huang Lin, New Taipei City (TW)

(21) Appl. No.: 18/172,323

(22) Filed: Feb. 22, 2023

(30) Foreign Application Priority Data
Jun. 27, 2022 (TW) 111123897

(51) Int. Cl. H05K 7/20

(52) U.S. Cl. CPC H05K 7/20336

(57) ABSTRACT

A vapor chamber structure includes a main body. The main body has multiple independent heat dissipation blocks. Each of the heat dissipation blocks has an internal independent airtight chamber. A capillary structure is disposed on an inner wall face of the airtight chamber. A working fluid is filled in the airtight chamber. Multiple connection bodies are disposed between the independent heat dissipation blocks to connect the independent heat dissipation blocks with each other. At least one heat insulation penetrating slot is formed between each two adjacent connection bodies to separate the heat dissipation blocks from each other so as to achieve heat insulation effect. By means of the heat insulation penetrating slots formed on the connection bodies, the respectively airtight chambers can independently conduct heat without transferring heat to each other.

This application claims the priority benefit of Taiwan patent application number 111123897 filed on Jun. 27, 2022.

### BACKGROUND OF THE INVENTION

### 1. Field of the Invention

The present invention relates generally to a vapor chamber structure, and more particularly to a vapor chamber structure having multiple independently arranged airtight chambers.

### 2. Description of the Related Art

In operation or calculation of a common electronic product (such as an intelligent device, a computer, a server or the like device with operation ability), the electronic product often generates heat due to the operation or the calculation. The more powerful the operation ability of the electronic device is, the faster the electronic device generates heat. In order to quickly conduct out the heat so as to avoid shutdown of the electronic device due to the heat, an active heat dissipation device and a passive heat dissipation device are often used to dissipate the heat.

In general, both the active heat dissipation device and passive heat dissipation device employ heat conduction components to dissipate the heat, wherein vapor chambers and heat pipes are most popularly used heat conduction components. The vapor chamber or the heat pipe has at least one internal vacuumed closed chamber. A capillary structure is disposed in the chamber and a working fluid is filled in the chamber to perform two-phase fluid heat exchange in the chamber for conducting the heat.

However, a conventional vapor chamber simply has one single vacuumed closed chamber for conducting heat. When the working range of the vapor chamber is larger, the heat conduction areas of the vapor chamber will too much spread and uneven. This will lead to deterioration of the heat conduction efficiency of the vapor chamber. In addition, there is a conventional vapor chamber, on which multiple vacuumed closed chambers are arranged. The vacuumed closed chambers are spaced from each other by quite short distances. The lip edges (sealed edges) for closing the chambers are apt to transfer heat to each other and affect each other. This causes deterioration of the heat conduction efficiency of the entire vapor chamber.

Furthermore, the vapor chamber with multiple closed chambers can provide multiple independent heat conduction blocks for multiple independent heat sources. However, the respective independent heat sources have different heights, while the heat conduction face of the vapor chamber is a plane plate body. Under such circumstance, the vapor chamber can hardly snugly attach to all the heat sources with different heights to conduct the heat generated by the heat sources.

In case of multiple heat sources with different heights, it is necessary to selectively employ multiple vapor chambers or heat pipes respectively in adaptation to the heat sources so as to contact the heat sources and conduct the heat generated by the heat sources. The peripheries of all the vapor chambers have lip edges. When arranging the vapor chambers, the lip edges of the vapor chambers will interfere with each other to cause trouble in arrangement. In the case that the vapor chambers are stacked, the total height will be increased or thermal resistance will be produced. Therefore, it is quite inconvenient to use the conventional vapor chambers.

It is therefore tried by the applicant to provide a vapor chamber structure to solve the above problem existing in the conventional vapor chambers. The vapor chamber structure singly has multiple independent chambers. The independent chambers can independently conduct heat without affecting each other. Therefore, the heat conduction areas of the vapor chamber are even. The vapor chamber is applicable to multiple heat sources with different heights to conduct the heat generated by the heat sources.

### SUMMARY OF THE INVENTION

It is therefore a primary object of the present invention to provide a vapor chamber structure, which singly has multiple independent airtight chambers.

It is a further object of the present invention to provide the above vapor chamber structure, in which the respective airtight chambers have equal or unequal heights or capacities.

To achieve the above and other objects, the vapor chamber structure of the present invention includes a main body. The main body has multiple independent heat dissipation blocks. Each of the heat dissipation blocks has an internal independent airtight chamber. A capillary structure is disposed on an inner wall face of the airtight chamber. A working fluid is filled in the airtight chamber. Multiple connection bodies are disposed between the independent heat dissipation blocks to connect the independent heat dissipation blocks with each other. The vapor chamber structure is characterized in that at least one heat insulation penetrating slot is formed between each two adjacent connection bodies. The heat insulation penetrating slot separates the heat dissipation blocks from each other so as to achieve heat insulation and heat interruption effect. At least one side of each of the heat dissipation blocks is formed with a heated section correspondingly in contact with at least one heat source for conducting heat.

At least one heat insulation penetrating slot is formed on the connection body connected between the adjacent airtight chambers. Therefore, the heat transfer medium and path between the respective independent airtight chambers of the main body are reduced. Accordingly, the heat conduction between the airtight chambers is reduced, whereby the adjacent airtight chambers have independent heat conduction areas without interfering with each other. In addition, the heated sections are recessed or raised so as to snugly contact the heat sources with different heights at the same time to conduct the heat. Accordingly, the vapor chamber structure of the present invention can singly provide multiple independent airtight chambers to conduct the heat generated by the heat sources with different heights.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a perspective exploded view of the vapor chamber structure of the present invention;

FIG. 2 is a perspective assembled view of the vapor chamber structure of the present invention;

FIG. 3 is a perspective sectional view of the vapor chamber structure of the present invention; and

FIG. 4 is a sectional view of the vapor chamber structure of the present invention, seen in another angle.

### DETAILED DESCRIPTION OF THE PREFERRED EMBODIMENTS

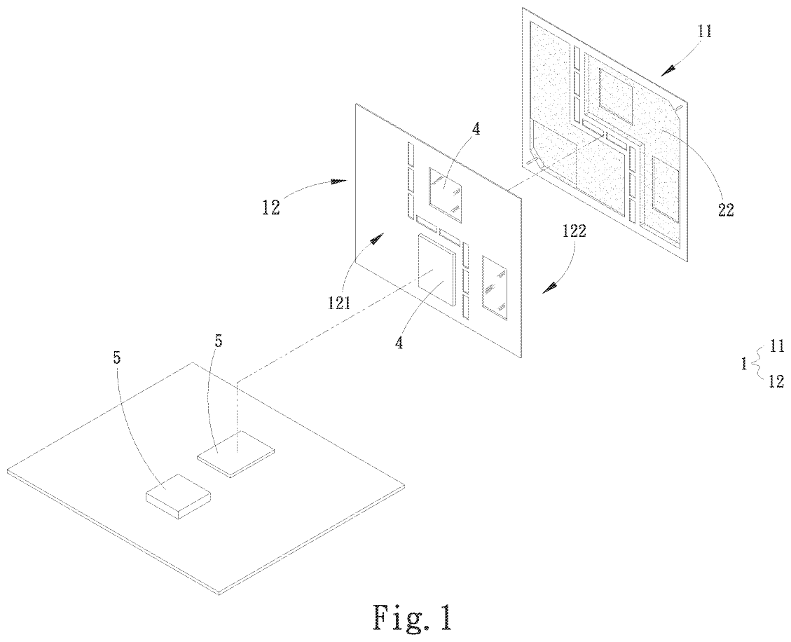

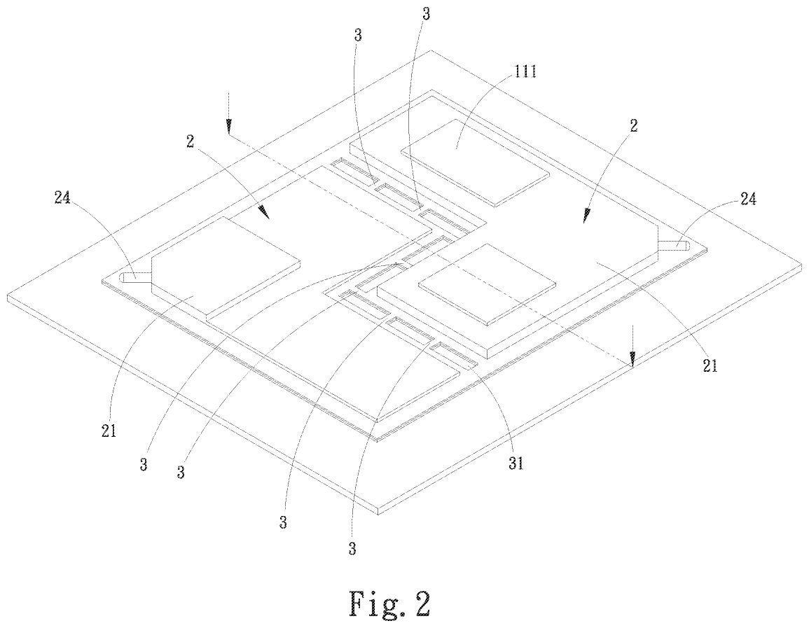

Please refer to FIGS. 1 and 2. FIG. 1 is a perspective exploded view of the vapor chamber structure of the present invention. FIG. 2 is a perspective assembled view of the vapor chamber structure of the present invention. As shown in the drawing, the vapor chamber structure of the present invention includes a main body 1.

The main body 1 has multiple independent heat dissipation blocks 2. Each of the heat dissipation blocks 2 has an internal independent airtight chamber 21. A capillary structure 22 is disposed on an inner wall face of the airtight chamber 21. A working fluid 23 is filled in the airtight chamber 21. Multiple connection bodies 3 are disposed between the independent heat dissipation blocks 2 to connect the independent heat dissipation blocks 2 with each other. The vapor chamber structure of the present invention is characterized in that each two adjacent connection bodies 3 together define therebetween at least one heat insulation penetrating slot 31 to separate (isolate) the heat dissipation blocks 2 from each other so as to achieve heat insulation and heat interruption effect. At least one side of each of the heat dissipation blocks 2 is formed with a heated section 4 correspondingly in contact with at least one heat source 5 for conducting heat.

The connection bodies 3 serve to serially connect (link) two adjacent independent heat dissipation blocks 2 with each other, whereby the heat dissipation blocks 2 are still integrated as a main body 1 to facilitate installation, transfer and manufacturing. Moreover, the heat insulation penetrating slot 31 is disposed between the two connection bodies 3 so as to reduce or cut off the heat transfer medium between the adjacent heat dissipation blocks 2. Accordingly, heat isolation, heat insulation or heat interruption effect is achieved between the adjacent heat dissipation blocks 2 so as to avoid interference between the heat dissipation blocks 2 in heat conduction.

The main body 1 has a first plate body 11 and a second plate body 12. The first plate body 11 is formed with multiple raised sections defining multiple raised section spaces 111. The first and second plate bodies 11, 12 are attached to each other to close the raised section spaces 111 so as to form the aforesaid airtight chambers 21. The second plate body 12 has an outer face 121 and an inner face 122. The outer face 121 is attached to the heat source 5. The inner face 122 is correspondingly connected with the first plate body 11. The outer face 121 is recessed toward the inner face 122 to form the heated section 4. Alternatively, the outer face 121 is outward raised in a direction away from the airtight chamber 21 to form the heated section 4. The raised or recessed heat sections 4 are positioned corresponding to different heights of heat sources 5. In addition, the airtight chambers 21 of the heat dissipation blocks 2 are connected with at least one water-filling air-sucking tube 24.

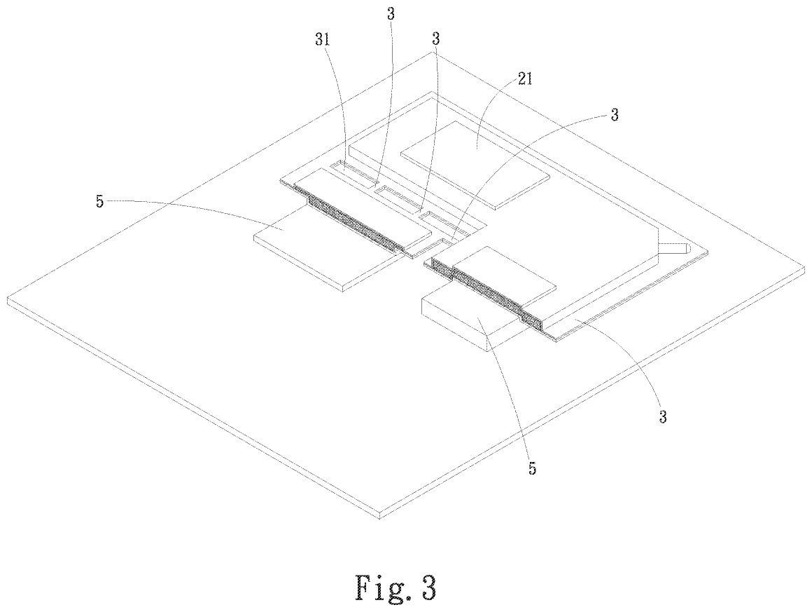

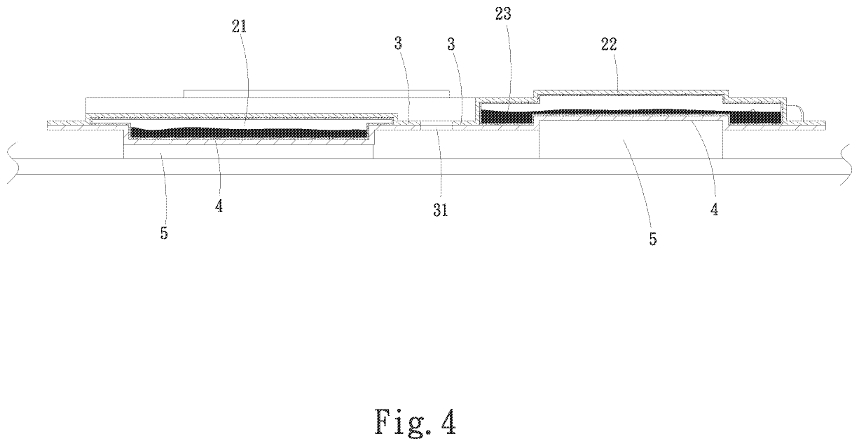

Please now refer to FIGS. 3 and 4. The heat sources corresponding to the airtight chambers 21 can have equal heights or unequal heights. The airtight chambers 21 can have different capacities corresponding to the different heat generation powers of the heat sources 5 for heat exchange. In addition, the heated sections 4 provide different depths of recessed spaces or different heights of raised platforms so as to snugly receive or attach to the corresponding heat sources 5 with different heights. In the case that the heated section 4 is recessed from the outer face 121 of the second plate body 12 in a direction toward the airtight chamber 21, the heated section 4 has a recessed space in adaptation to a higher heat source 5. Alternatively, in the case that the heated section 4 is raised from the outer face 121 of the second plate body 12 in a direction away from the airtight chamber 21, the heated section 4 is an outward raised platform in adaptation to a lower heat source 5. Accordingly, the heated sections 4 can respectively fully snugly attach to the heat sources 5 with different heights at the same time so as to transfer the heat to the airtight chambers 21.

Moreover, the airtight chambers 21 can selectively have equal or unequal capacities for correspondingly transferring the heat generated by the heat sources 5 with different heat generation powers. An airtight chamber 21 with a larger capacity is applied to a heat source 5 with higher heat generation power, whereby the airtight chamber 21 has higher heat dissipation or heat conduction efficiency sufficient for transferring the heat generated by the heat source 5. Similarly, an airtight chamber 21 with a smaller capacity is applied to a heat source 5 with lower heat generation power, whereby the airtight chamber 21 can satisfy lower heat transfer requirement and the thickness of the main body 1 can be reduced.

In the present invention, the heat insulation penetrating slots 31 are formed on the connection bodies 3 connected between the adjacent airtight chambers 21. Therefore, the connection sections between the respectively independent airtight chambers 21 of the main body 1 are greatly reduced so that the heat transfer medium and path between the independent airtight chambers 21 are reduced. Accordingly, the heat conduction between the airtight chambers 21 is avoided, whereby the adjacent airtight chambers 21 have independent heat conduction areas without interfering with each other.

The present invention has been described with the above embodiments thereof and it is understood that many changes and modifications in such as the form or layout pattern or practicing step of the above embodiments can be carried out without departing from the scope and the spirit of the invention that is intended to be limited only by the appended claims.

What is claimed is:

1. A vapor chamber structure comprising a main body, the main body having multiple independent heat dissipation blocks, each of the heat dissipation blocks having an internal independent airtight chamber, a capillary structure being disposed on an inner wall face of the airtight chamber, a working fluid being filled in the airtight chamber, multiple connection bodies being disposed between the independent heat dissipation blocks to connect the independent heat dissipation blocks with each other, the vapor chamber structure being characterized in that at least one heat insulation penetrating slot is formed between each two adjacent connection bodies, the heat insulation penetrating slot separating the heat dissipation blocks from each other so as to achieve heat insulation (isolation) effect, at least one side of each of the heat dissipation blocks being formed with a heated section correspondingly in contact with at least one heat source for conducting heat.

2. The vapor chamber structure as claimed in claim 1, wherein the main body has a first plate body and a second plate body, the first plate body being formed with multiple raised sections defining multiple raised section spaces, the first and second plate bodies being attached to each other to close the raised section spaces so as to form the aforesaid airtight chambers.

3. The vapor chamber structure as claimed in claim 2, wherein the second plate body has an outer face and an inner face, the outer face being attached to the heat source, the inner face being correspondingly connected with the first plate body, the outer face being recessed toward the inner face to form the heated section.

4. The vapor chamber structure as claimed in claim 1, wherein the airtight chambers are connected with a water-filling air-sucking tube.

5. The vapor chamber structure as claimed in claim 1, wherein the airtight chambers have unequal capacities.

6. The vapor chamber structure as claimed in claim 3, wherein the heated section is recessed from the outer face of the second plate body toward the airtight chamber.

7. The vapor chamber structure as claimed in claim 3, wherein the heated section is outward raised from the outer face of the second plate body in a direction away from the airtight chamber.
